(19) United States
(12) Patent Application Publication
(10) Pub. No.: US 2006/0284191 A1
(43) Pub. Date: Dec. 21, 2006

(54) Light emitting diode

(75) Inventors: Cheng Chung Yang, Hsinchu (TW); Charng-Shyang Jong, Hsinchu (TW); Chuan-Cheng Tu, Hsinchu (TW); Kau-Feng Jan, Hsinchu (TW); Jen-Chau Wu, Hsinchu (TW)

Correspondence Address: INGRASSIA FISHER & LORENZ, P.C., 7150 E. CAMELBACK, STE. 325, SCOTTSDALE, AZ, 85251, US

(73) Assignee: EPISTAR CORPORATION

(21) Appl. No.: 11/454,951

(22) Filed: Jun. 15, 2006

(30) Foreign Application Priority Data
Jun. 16, 2005 (TW) 94119970

(51) Int. Cl. H01L 33/00

(52) U.S. Cl. 257/79

(57) ABSTRACT

A light emitting diode includes a light emitting structure, a heterojunction, a first electrode, and a second electrode. The light emitting structure has a top surface where the first electrode and the second electrode are positioned thereon. The heterojunction is in the light emitting structure and includes a first semiconductor layer and a second semiconductor layer of differently doped types. The first semiconductor layer has a boundary and is electrically connected to the first electrode. The first electrode includes at least two wire-bonding pads. A smallest horizontal distance (d) between a center of the first electrode and the boundary is in a range of about 89 μm to 203 μm. The second electrode is electrically connected to the second semiconductor layer and includes an outer arm, which peripherally encompasses the top surface.

### CROSS REFERENCE TO RELATED APPLICATIONS

This application claims the right of priority based on Taiwan Patent Application No. 094119970 entitled “Light Emitting Diode”, filed on Jun. 16, 2005, which is incorporated herein by reference and assigned to the assignee herein.

### TECHNICAL FIELD

The present invention generally relates to a light emitting diode, and more particularly to a light emitting diode with improved electrode design.

### BACKGROUND OF THE INVENTION

Light emitting diodes (LEDs) are different from conventional light sources and are more applicable to different industrial fields because of their unique structures and characteristics of emitting lights. For example, LEDs are characterized by low production cost, simple structure, low power consumption, small size, and the easiness to install, so they are suitable for many kinds of applications including but not limited to traffic signaling, electronic sign, instrumentation, display, and illumination.

FIG. 1 illustrates a schematic structural top view of a conventional LED 10. As shown in FIG. 1, when a voltage is applied to the p-type electrode 110, the current flows through the p-n junction (not shown) to the n-type electrode 120. Because the p-type electrode 110 is disposed on the diagonal position with respect to the n-type electrode 120, i.e., the p-type electrode 110 and the n-type electrode 120 are kept apart by a substantially largest distance, a substantially largest light emitting area (along the diagonal direction) is accordingly formed. The current from the p-type electrode 110 to the n-type electrode 120 may flow via various paths, such as paths 130, 140, and 150. However, the current is most likely to flow via the shortest path 140 and gathers along the path 140, thereby leading to nonuniform current distribution. Furthermore, it is not suitable to place the p-type electrode in the diagonal location with respect to the n-type electrode for a large-sized LED application. This is due to the long distance between the p-type and n-type electrodes while only a single contact area (p-type electrode) is provided for inputting voltage. As a result, the light emitting efficiency of the LED is greatly decreased.

FIG. 2A illustrates a schematic structural top view of another conventional LED 20. As shown in FIG. 2A, the part in shade indicates a light emitting area. The p-type electrode 210 includes multiple parallel p-type arms 214 and 216. The n-type electrode 220 includes multiple parallel n-type arms 222, 224, and 226. The p-type arm 214 is equally distanced from the adjacent n-type arms 222 and 224; and the p-type arm 216 is equally distanced from the adjacent n-type arms 224 and 226. Compared to the LED 10 in FIG. 1, the electrode configuration of LED 20 allows the current flowing from the p-type electrode 210 to the n-type electrode 220 via a shorter and equal distance so as to provide a uniform illumination suitable for large-sized LED application.

However, both LED 10 in FIG. 1 and LED 20 in FIG. 2A have the issue of low light-emitting efficiency. For example, referring to FIG. 2B, due to the defects in the edge region (the shaded region) 250 of the p-type semiconductor layer 240, the current (as indicated by the arrow) flowing from the p-type electrode 210 into the edge region 250 has a tendency to adversely affect the light emitting efficiency of the LED 20. In accordance with a prior art technology, the electrode is disposed close to the edge of the LED to increase the light emitting area, thereby improving the light-emitting efficiency. However, this technology cannot avoid the above-mentioned issue caused by the defects in the edge region, which is critical to the large-sized LED illumination application.

Therefore, it is desirable to provide an LED with uniform and high illumination output, especially for the large-sized LED application.

### SUMMARY OF THE INVENTION

An object of the invention is to provide a light emitting diode, which avoids the reduced light-emitting efficiency issue as occurred in conventional light emitting diodes and provides high and uniform illumination output.

In an embodiment of the present invention, a light emitting diode includes a light emitting structure, a heterojunction, a first electrode, and a second electrode. The light emitting structure has a top surface where the first electrode and the second electrode are positioned thereon. The heterojunction is in the light emitting structure and includes a first semiconductor layer and a second semiconductor layer, which are respectively doped with different types of impurities. The first semiconductor layer has a boundary. The first electrode is electrically connected to the first semiconductor layer and includes at least two wire-bonding pads. A smallest horizontal distance (d) between the center of the first electrode and the boundary is in a range of about 89 μm to 203 μm (89 μm □ d □ 203 μm). The second electrode is electrically connected to the second semiconductor layer and includes an outer arm for peripherally encompassing the top surface.

### BRIEF DESCRIPTION OF THE DRAWINGS

The foregoing object and other objects together with the advantages of this invention will become more readily appreciated as the same becomes better understood by reference to the following detailed description, when taken in conjunction with the accompanying drawings, wherein:

FIG. 1 is a schematic top view of a conventional light emitting diode;

FIG. 2A is a schematic top view of another conventional light emitting diode;

FIG. 2B is a partially cross-sectional view along line k-k′ of FIG. 2A;

FIG. 3A is a schematic top view of a light emitting diode in accordance with an embodiment of the present invention;

FIG. 3B is a partially cross-sectional view along line I-I′ of FIG. 3A;

FIG. 4A is a schematic diagram illustrating input voltage v. input current relation of an embodiment of the present invention and that of a conventional LED;

FIG. 4B is a schematic diagram illustrating input current v. output power relation of an embodiment of the present invention and that of a conventional LED; and

FIGS. 5-9 are schematic top views illustrating other embodiments in accordance with the present invention.

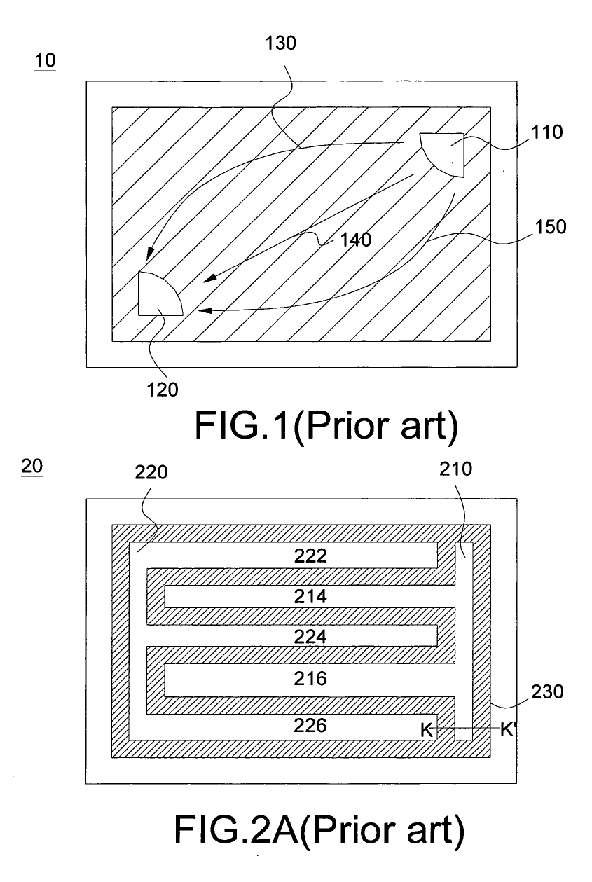

### DETAILED DESCRIPTION OF THE INVENTION

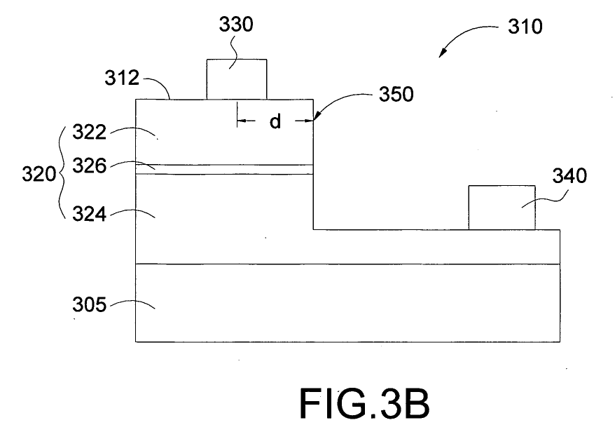

Referring to FIGS. 3A and FIG. 3B, the LED 30 includes a light emitting structure 310, a heterojunction 320, a first electrode 330, and a second electrode 340. The light emitting structure 310 has a top surface 312. The heterojunction 320 is in the light emitting structure 310. A substrate 305 is provided below the heterojunction 320. The heterojunction 320 includes a first semiconductor layer 322, a second semiconductor layer 324, and an active layer 326. The first semiconductor layer 322 and the second semiconductor layer 324 are doped with different types of impurities. For example, the first semiconductor layer 322 can be p-type doped, while the second semiconductor layer 324 can be n-type doped. Corresponding to the p-type semiconductor layer 322 and the n-type semiconductor layer 324, the first electrode 330 and the second electrode 340 can be a p-type electrode and an n-type electrode, respectively. The first electrode 330 and the second electrode 340 are electrically connected to the first semiconductor layer 322 and the second semiconductor layer 324, respectively. In other words, the p-type electrode 330 is electrically connected to the p-type semiconductor layer 322, while the n-type electrode 340 is electrically connected to the n-type semiconductor layer 324.

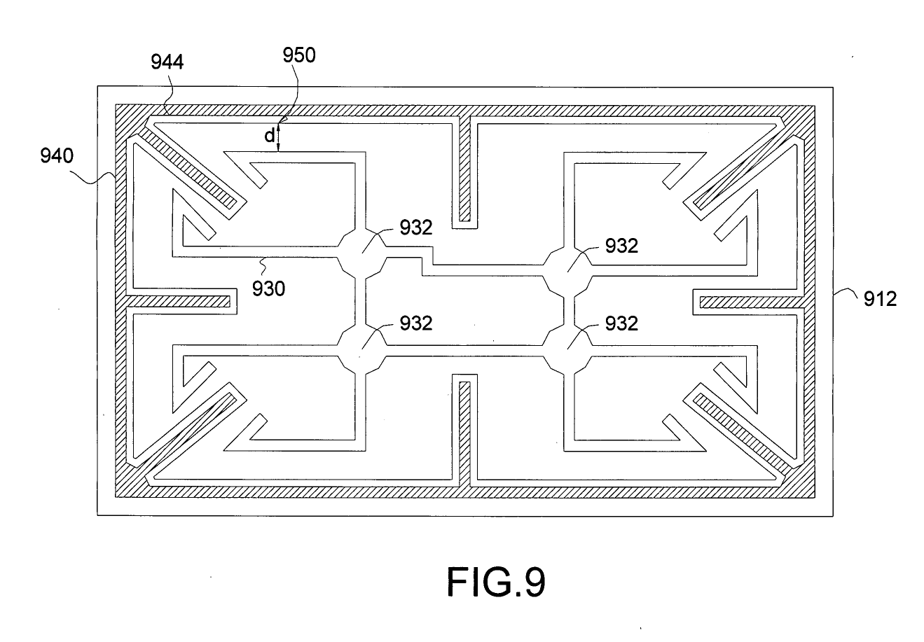

In an embodiment of the present invention, the top surface 312 of the LED 30 has an area larger than 450 μm². Accordingly, the LED 30 is classified as a large-sized LED. In another embodiment of the present invention, the top surface 312 of the LED 30 has an area larger than 1000 μm². The first electrode 330 includes at least two connecting portions 332 (i.e. wire-bonding pads) so as to provide connections on the large area top surface 312 for inputting voltage. It is noted that though two wire-bonding pads 332 are shown in FIG. 3A, the number of the wire-bonding pads 322 is not limited to that as illustrated in this embodiment and can vary with different design need. For example, more wire-bonding pads means more flexible design of serial or parallel circuit. It is noted that at least two wire-bonding pads 322 are required in the present invention. Preferably, four wire-bonding pads 322 are implemented (as shown in FIG. 9) to provide sufficient connections.

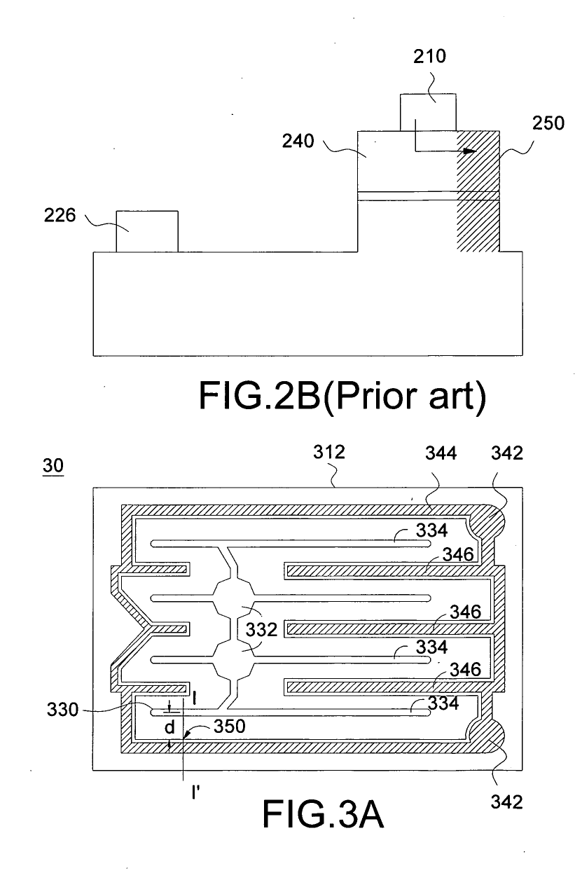

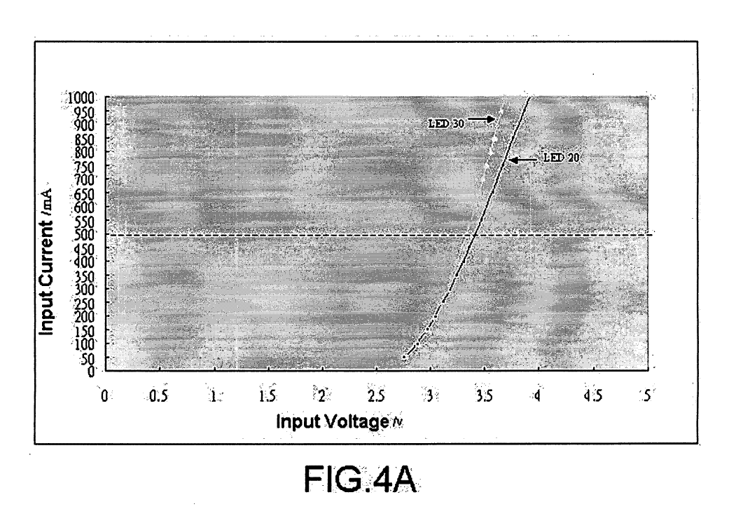

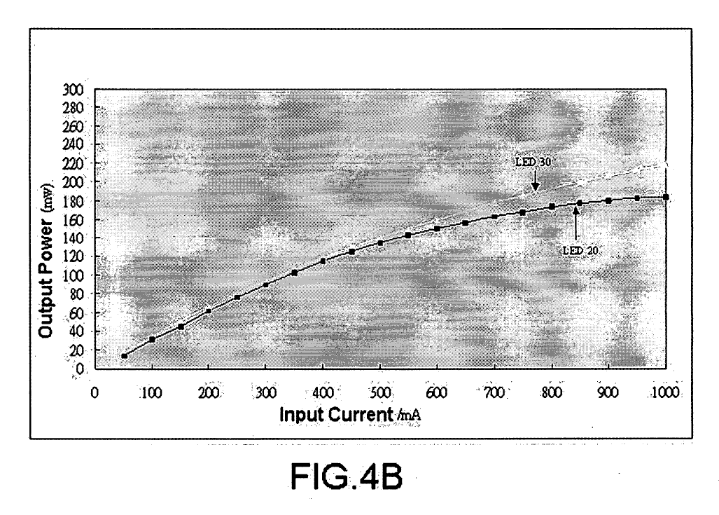

The second electrode 340 includes wire-bonding pads 342 and an outer arm 344. The wire-bonding pads 342 are implemented to lead out the current of the second electrode 340. It is noted that though two wire-bonding pads 342 are shown in FIG. 3A, the number of the wire-bonding pads 342 is not limited to the number as illustrated in this embodiment and can vary with different design needs. The outer arm 344 substantially peripherally encompasses the top surface 312, as shown in FIG. 3A. Compared to the LED 20 in FIG. 2A, the outer arm 344 of the LED 30 shown in the embodiment of FIG. 3A peripherally encompasses the top surface 312, and substantially completely surrounds the first electrode 330. FIGS. 4A and 4B illustrate the comparisons of electric properties of LED 20 and LED 30. FIG. 4A illustrates a schematic diagram of input voltage v. input current relation of LED 20 and LED 30. As shown in FIG. 4A, when the input current (i.e. operating current) increases, the LED 30 of the present invention requires less input voltage than that of the conventional LED 20. In other words, the resistance of LED 30 is smaller than that of the conventional LED 20. For example, as the input current is 500 mA, the LED 30 of the present invention requires an input voltage of about 3.3 volt (V), while the conventional LED 20 requires an input voltage of about 3.4 V. FIG. 4B is a schematic diagram illustrating input current v. output power of LED 30 and LED 20. As shown in FIG. 4B, when the input current increases, the output power of the LED 30 of the present invention significantly increases than that of the conventional LED 20. In other words, the resistance of LED 30 is smaller than that of the conventional LED 20. Consequently, the present invention can provide higher input current and higher the output power for a given input voltage in a large-sized LED application.

In comparison with the conventional technique that the first electrode is disposed close to the edge of the top surface, in one embodiment (FIGS. 3A and 3B) of the present invention, the first electrode 330 is surrounded by the outer arm 344 of the second electrode 340. The first electrode 330 of the present invention is not close to the edge of the top surface. Furthermore, the manufacture of the light emitting structure 310 starts from forming the heterojunction 320 on the substrate 305, then the first semiconductor layer 322, the active layer 326, and the semiconductor layer 324 are etched in, for example, an reactive ion etch (RIE) process. Due to this process, the region of the semiconductor layer 322 close to the boundary 350 is susceptible to the generation of defects. Accordingly, the first electrode 330 configured to be applied with voltage thereto is preferably not too close to the boundary 350. On the other hand, in order to prevent the current crowding issue and to optimize the current distribution, the first electrode is preferably closer to the boundary 350 so as to obtain a better light emitting efficiency. The present invention attempts to balance the contradiction between these two concerns, and an appropriate horizontal distance (d, as shown in FIGS. 3A and 3B) between the center of the first electrode 330 and the boundary 350 is found as in a range of about 89 μm (about 3.5 mil) to 203 μm (about 8 mil) (89 μm<d<203 μm), and preferably in a range of about 102 μm (about 4 mil) to 152 μm (6 mil) (102 μm<d<152 μm).

In an embodiment, the first electrode 330 includes multiple inner arms parallel with each other, referred to as the first inner arms 334. The second electrode 340 also includes multiple inner arms parallel with each other, referred to as the second inner arms 346. The first inner arms 334 and the adjacent second inner arm 346 are equally distanced and parallel. Accordingly, the current flowing from the first electrode 334 to the second electrode 346 are through a substantial shorter and equal distance so as to provide a high and uniform illumination output.

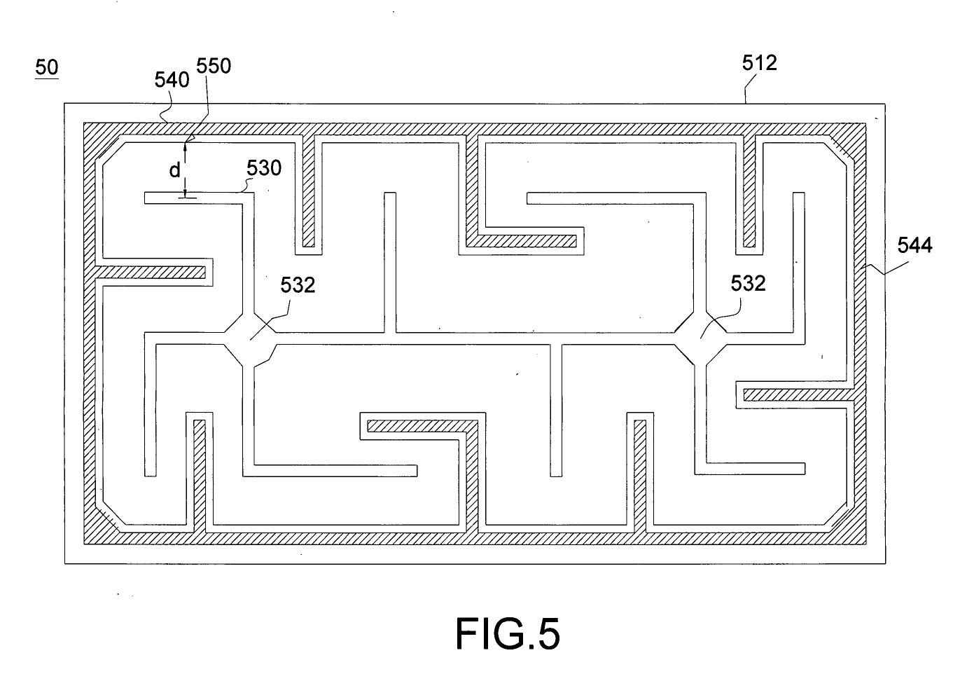

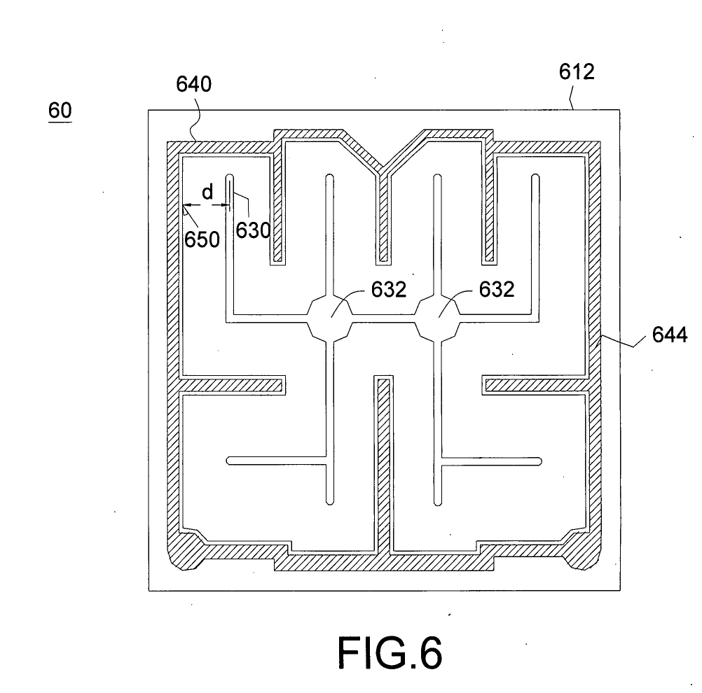

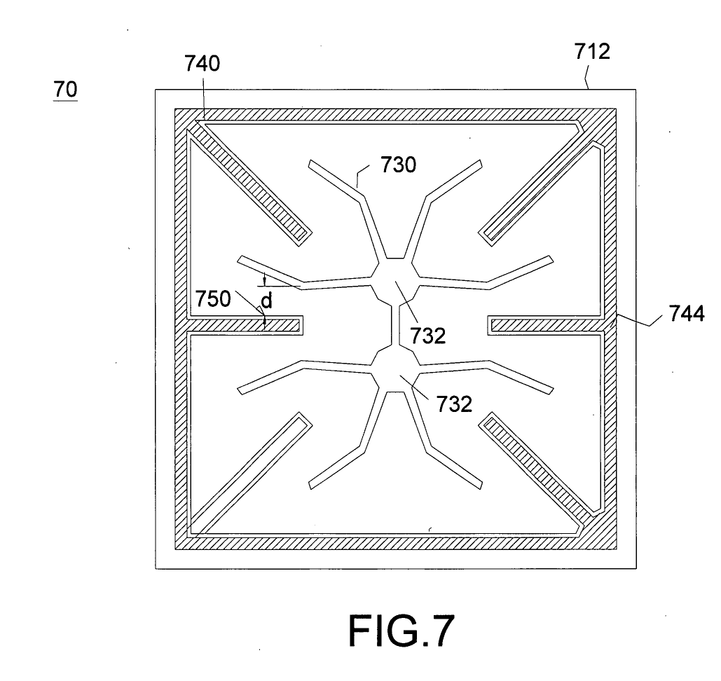

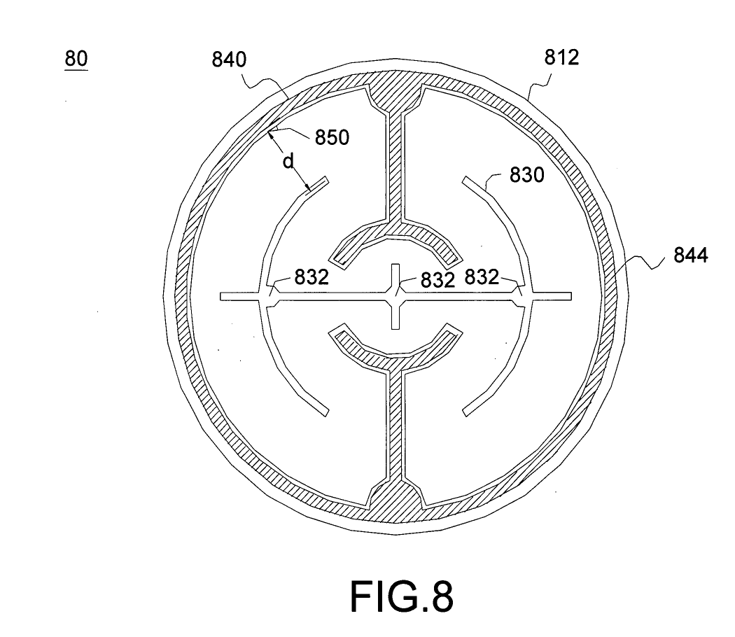

Referring to FIG. 5, the first electrode (p-type electrode) 530 includes at least two wire-bonding pads 532. The horizontal distance (d) between the center of the first electrode 530 to the boundary 550 of the first semiconductor layer is in a range of about 89 μm (about 3.5 mil) to 203 μm (about 8 mil) (89 μm<d<203 μm), and preferably in a range of about 102 μm (about 4 mil) to 152 μm (about 6 mil) (102 μm<d<152 μm). Referring to FIGS. 6-9, the LED 60, 70, 80, and 90 respectively includes a first electrode 630, 730, 830, and 930, a second electrode 640, 740, 840, and 940, a boundary 650, 750, 850, and 950, at least two wire-bonding pads 632, 732, 832, and 932, and an outer arm 644, 744, 844, and 944, which are similar to those described in FIGS. 3A and 5 and not elaborated again.

Although specific embodiments have been illustrated and described, it will be apparent that various modifications may fall within the scope of the appended claims.

We claim:

1. A light emitting diode, comprising:
a light emitting structure comprising a top surface;
a heterojunction, in said light emitting structure, comprising a first semiconductor layer and a second semiconductor layer of differently doped types, said first semiconductor layer having a boundary;
a first electrode on said top surface, said first electrode being electrically connected to said first semiconductor layer and comprising at least two wire-bonding pads, wherein a smallest horizontal distance, d, between a center of said first electrode and said boundary is in a range of about 89 μm to 203 μm; and
a second electrode on said top surface, said second electrode being electrically connected to said second semiconductor layer and comprising an outer arm for peripherally encompassing said top surface.

2. The light emitting diode of claim 1, wherein said smallest horizontal distance is in a range of about 102 μm to 152 μm.

3. The light emitting diode of claim 1, wherein said first electrode comprises multiple inner arms parallel to one another.

4. The light emitting diode of claim 1, wherein said second electrode comprises multiple inner arms parallel to one another.

5. The light emitting diode of claim 1, wherein said top surface has an area not less than about 450 μm².

6. The light emitting diode of claim 1, wherein said top surface has an area not less than 1000 μm².

7. The light emitting diode of claim 1, wherein said first electrode is a p-type electrode, and said second electrode is an n-type electrode.

8. A light emitting diode, comprising:
a light emitting structure comprising a top surface with an area not less than 450 μm²;
a heterojunction, in said light emitting structure, comprising an n-type semiconductor layer and a p-type semiconductor layer, said p-type semiconductor layer having a boundary;
a p-type electrode on said top surface, said p-type electrode being electrically connected to said p-type semiconductor layer and comprising at least two p-type bonding pads, wherein a smallest horizontal distance, d, between a center of said p-type electrode and said boundary is in a range of about 89 μm to 203 μm; and
an n-type electrode on said top surface, said n-type electrode being electrically connected to said n-type semiconductor layer and comprising an n-type outer arm for peripherally encompassing said top surface.

9. The light emitting diode of claim 8, wherein said n-type electrode comprises at least one n-type bonding pad and multiple n-type inner arms parallel to one another.

10. The light emitting diode of claim 8, wherein said p-type electrode comprises multiple p-type inner arms, and said multiple p-type inner arms are parallel to one another.

11. The light emitting diode of claim 8, wherein said smallest distance is in a range of about 102 μm to 152 μm.

12. The light emitting diode of claim 8, wherein said top surface has an area not less than about 1000 μm².

13. A light emitting diode, comprising:
a light emitting structure comprising a top surface with an area not less than about 450 μm²;
a heterojunction, in said light emitting structure, comprising an n-type semiconductor layer and a p-type semiconductor layer;
a p-type electrode on said top surface, said p-type electrode being electrically connected to said p-type semiconductor layer and comprising at least two p-type bonding pads; and
an n-type electrode on said top surface, said n-type electrode being electrically connected to said n-type semiconductor layer and comprising an n-type outer arm for peripherally encompassing said top surface.

14. The light emitting diode of claim 13, wherein said p-type semiconductor layer comprises a boundary, and a smallest horizontal distance, d, between a center of said p-type electrode and said boundary is in a range of about 89 μm to 203 μm.

15. The light emitting diode of claim 13, wherein said p-type semiconductor layer comprises a boundary, and a smallest horizontal distance, d, between a center of said p-type electrode and said boundary is in a range of about 102 μm to 152 μm.

16. The light emitting diode of claim 13, wherein said top surface has an area not less than about 1000 μm².
